(19) United States
(12) Patent Application Publication
(10) Pub. No.: US 2020/0243386 A1
(43) Pub. Date: Jul. 30, 2020

(54) METHOD FOR FABRICATING SEMICONDUCTOR DEVICE

(71) Applicant: United Microelectronics Corp., Hsinchu (TW)

(72) Inventors: CHU-FU LIN, Kaohsiung City (TW); Ming-Tse Lin, Hsinchu City (TW); Chun-Hung Chen, Tainan City (TW)

(73) Assignee: United Microelectronics Corp., Hsinchu (TW)

(21) Appl. No.: 16/258,389

(22) Filed: Jan. 25, 2019

(51) Int. Cl. H01L 21/768; H01L 23/48; H01L 21/311

(52) U.S. Cl. CPC H01L 21/76898; H01L 21/31116; H01L 21/76831; H01L 23/481

(57) ABSTRACT

A method for fabricating semiconductor device includes providing a preliminary device layer, having a substrate on top and a through substrate via (TSV) structure in the substrate. A top portion of the TSV structure protrudes out from the substrate. A dielectric layer is disposed over the substrate to cover the substrate and the TSV structure. A coating layer is formed over the dielectric layer, wherein the coating layer fully covers over the dielectric layer with a flat surface. An anisotropic etching process is performed to the coating layer and the dielectric layer without etching selection until the TSV structure is exposed.

### BACKGROUND

### 1. Field of the Invention

The present invention generally relates to semiconductor fabrication technology, and particularly to a method for fabricating a semiconductor device with structure of through substrate via (TSV).

### 2. Description of Related Art

To have more function to the integrated circuit, various devices are formed on both sides of a substrate, so to have more devices to be integrated together. The devices at the two sides of the silicon substrate need to be connected according to the route of the design circuit. The TSV structure is then involved in the interconnection to connect the devices at both sides of the substrate.

However, the TSV structure is involving a polishing process, which may cause a defect at the end peripheral region of the TSV. How to fabricate the TSV structure with reduction of damage is still at least an issue under consideration.

### SUMMARY OF THE INVENTION

The invention provides a method for fabricating semiconductor device, which involving a TSV structure. The damage to the substrate due to polishing effect may at least be reduced or excluded.

In an embodiment, the invention provides a method for fabricating semiconductor device includes providing a preliminary device layer, having a substrate on top and a through substrate via (TSV) structure in the substrate. A top portion of the TSV structure protrudes out from the substrate. A dielectric layer is disposed over the substrate to cover the substrate and the TSV structure. A coating layer is formed over the dielectric layer, wherein the coating layer fully covers over the dielectric layer with a flat surface. An anisotropic etching process is performed to the coating layer and the dielectric layer without etching selection until the TSV structure is exposed.

In an embodiment, as to the method for fabricating semiconductor device, the dielectric layer is oxide layer and the coating layer is a photoresist layer.

In an embodiment, as to the method for fabricating semiconductor device, the coating layer provides the flat surface before the anisotropic etching process.

In an embodiment, as to the method for fabricating semiconductor device, the coating layer is a dielectric material formed by a spin coating process.

In an embodiment, as to the method for fabricating semiconductor device, the coating layer and the dielectric layer are oxide materials as etched by the anisotropic etching process.

In an embodiment, as to the method for fabricating semiconductor device, the anisotropic etching process is an etching back process.

In an embodiment, as to the method for fabricating semiconductor device, before performing the anisotropic etching process, a polishing process is further performed stating from the coating layer but not to expose the TSV structure.

In an embodiment, as to the method for fabricating semiconductor device, wherein a thickness of the dielectric layer is substantially equal to or larger than the top portion of the TSV structure.

In an embodiment, as to the method for fabricating semiconductor device, after the anisotropic etching process, the coating layer is fully removed, and a residue of the dielectric layer on the substrate is surrounding the top portion of the TSV structure.

In an embodiment, as to the method for fabricating semiconductor device, the TSV structure comprises a metal via; and a liner insulating layer on the sidewall of the metal via to insulate the metal via from the substrate.

In an embodiment, as to the method for fabricating semiconductor device, the method further comprises a subsequent process over the TSV structure and the dielectric layer.

In an embodiment, as to the method for fabricating semiconductor device, the substrate is a silicon substrate.

In an embodiment, as to the method for fabricating semiconductor device, the dielectric layer comprises an oxide layer, a nitride layer, an oxide layer stacked with a nitride layer, or a first oxide layer stacked with a nitride layer and with a second oxide layer.

In an embodiment, as to the method for fabricating semiconductor device, the coating layer is a photoresist layer, and the method further comprises stripping a portion of the photoresist layer.

In an embodiment, as to the method for fabricating semiconductor device, the preliminary device layer comprises a device layer, disposed on the carrier. The substrate is disposed on the device layer. The TSV structure is in the substrate with connection to a device of the device layer.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1D are drawings, schematically illustrating the method for fabricating semiconductor device as looked into by the invention, according to an embodiment of the invention.

FIGS. 2A-2D are drawings, schematically illustrating the method for fabricating semiconductor device, according to an embodiment of the invention.

### DESCRIPTION OF THE EMBODIMENTS

The invention is directed to a method for fabricating semiconductor device with a TSV structure.

The invention has looked into the usual way to fabricate the semiconductor device with the TSV structure and addressed at least an issue after looking into the fabrication procedure. The invention has provided multiple embodiments to describe the invention but the invention is not just limited to the embodiments as provided. Some embodiments may also be suitablly combined into another embodiment.

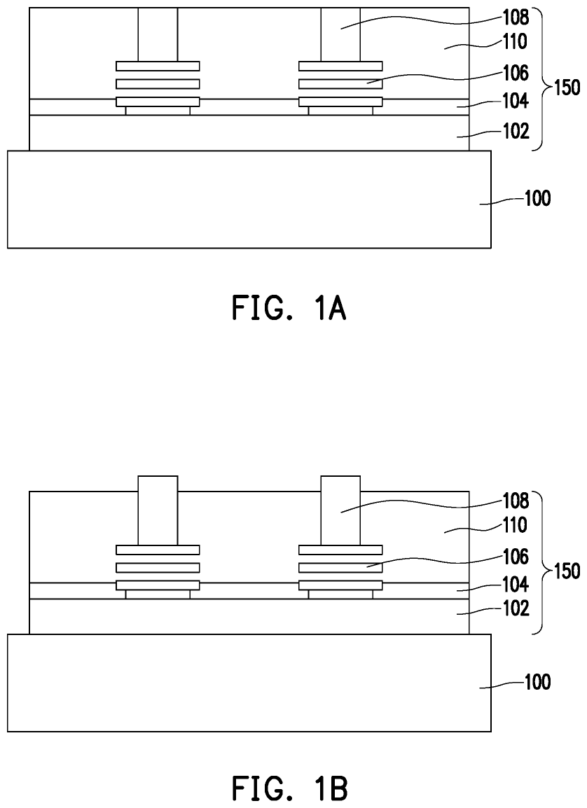

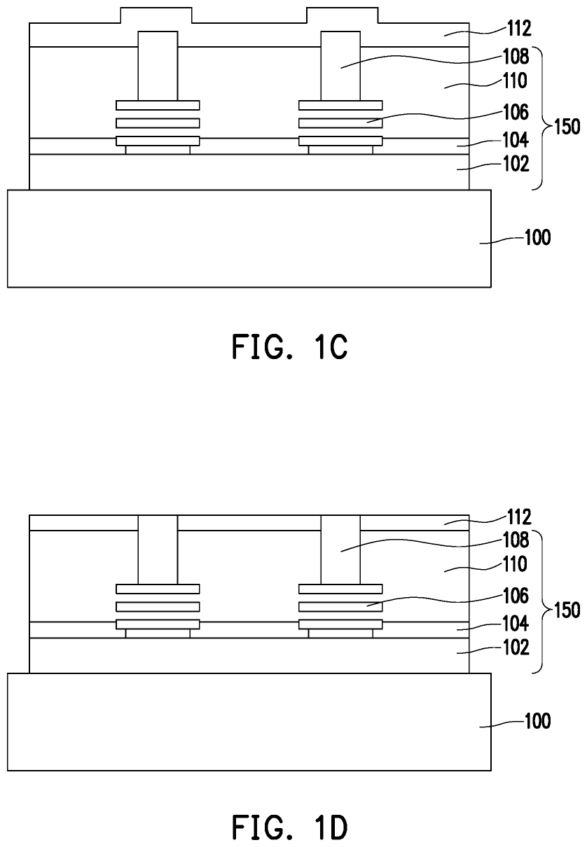

FIGS. 1A-1D are drawings, schematically illustrating the method for fabricating semiconductor device as looked into by the invention, according to an embodiment of the invention.

Referring to FIG. 1A, for the semi-completed semiconductor structure, it may include a preliminary device layer 150, disposed on a carrier 100. The carrier 100 is a supporting substrate for supporting the preliminary device layer 150 in fabrication. As usually known, the carrier 100 is not a part of the semiconductor device and would be stripped away after completion of the semiconductor device.

The preliminary device layer 150 may include an oxide layer 102 with nitride layer 104, serving as an inter-layer dielectric layer so to form the device 106 and adhere on the carrier 100 during fabrication. Various devices 106 include various components in the substrate 110 and the inter-layer dielectric layer as usually known in the art without detail descriptions. The substrate 110 is silicon substrate, and other devices not described here are to be subsequently formed over the substrate 110 at the other side opposite to the devices 106.

To have the electric connection to the device 106 and the device subsequently to be formed on the substrate 110 at the other side, a TSV structure 108 is also formed. The TSV structure 108 in an example includes a metal via with insulating layer at the periphery to insulate from the substrate 110.

Referring to FIG. 1B, a top portion of the TSV structure 108 is exposed by etching the silicon material of the substrate 110.

Referring to FIG. 1C, a dielectric layer 112 is deposited over the substrate 110 and covering over the exposed top portion of the TSV structure 108.

Referring to FIG. 1D, a polishing process, such as the chemical mechanical polishing (CMP) process, is performed to expose the TSV structure 108. As a result, the top portion of the TSV structure 108 is surrounded by the dielectric layer 112 with a flat surface.

As looking into the procedures in FIG. lA to FIG. 1D, the CMP process is involved, so top periphery interface between the TSV structure 108 and the dielectric layer 112 may be not polished well, and a crack or indent may occur, causing damage.

After looking into the issue may occur, the invention proposes forming a coating layer such as photoresist layer or spin coating layer over the dielectric layer and obtain a rather flat plane on top. Then, an anisotropic etching process, such as dry etching, without etching selection to the coating layer and the dielectric layer may be performed to uniformly remove the coating layer and the dielectric layer until TSV structure is exposed. The further embodiments are further provided.

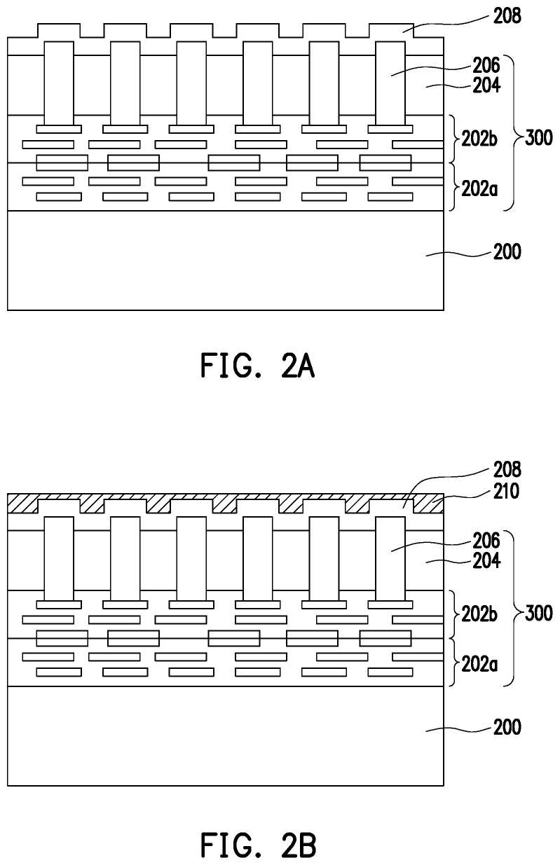

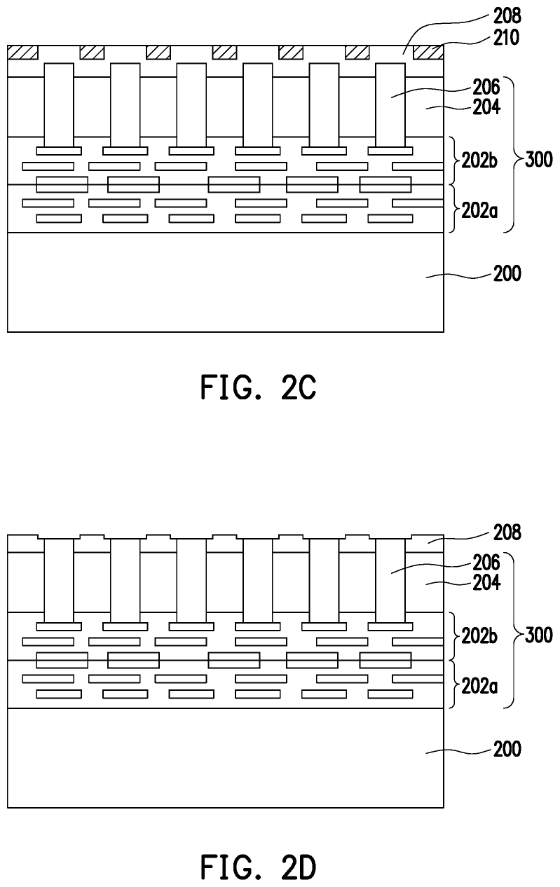

FIGS. 2A-2D are drawings, schematically illustrating the method for fabricating semiconductor device, according to an embodiment of the invention.

Referring to FIG. 2A, a preliminary device layer 300 is disposed on a carrier 200. The carrier is for mechanical supporting during fabrication but not actually a part of the semiconductor device. The carrier 200 is a temporary bonding layer such as glass substrate or any like substrate, which may be finally stripped away. The preliminary device layer 300 includes the device layers 202a, 202b, a substrate 204 and a TSV structure 206. The device layer 202a and the device layer 202b may be joined together as a device layer in single layer as generally addressed, according to the fabrication procedure in stack manner. The device layer 202a, 202b may include various device components depending on the integrated circuit as designed, without being described in detail.

The other various devices would be subsequently formed over the substrate 204 in the subsequence fabrication procedure. There devices to subsequently formed are electrically connected to the device layer 202a, 202b by the TSV structure 206. The TSV structure 206 has a top portion protruding out from the substrate 204, such as silicon substrate. The TSV structure 206 in an embodiment includes the metal material such as Cu. The periphery sidewall also has the insulating layer to insulate from the silicon substrate 204.

The invention has proposed a method for fabrication the TSV structure 206 with less probability in causing damage. Referring to FIG. 2B, a coating layer 210 is formed over the substrate 204 and the exposed top portion of the TSV structure 206. Due to the liquid state in coating stage, after curing, the coating layer 210 may cover over the TSV structure 206 with a rather flat surface op top.

The coating layer 210 in an embodiment may be a photoresist layer or the oxide layer formed by spin coating process. The coating layer may fill the indent portion and then obtain the flat surface op top.

Referring to FIG. 2C, an anisotropic etching process is performed on the coating layer 210 to expose the dielectric layer 208 first. The etchant of the anisotropic etching process is chosen to have no etching selection to the coating layer 210 and the dielectric layer 208, so that the flat surface on top may still remain. In an embodiment, both of the coating layer 210 and the dielectric layer 208 may be the oxide, then the recipe of the etchant may be easily made. In an embodiment, the etching process includes the stage to strip the photoresist material, if the coating layer 210 is a photoresist coating layer. The invention is not limited to the specific coating layer. The coating layer 210 may provide the flat surface, so that the TSV structure may be exposed by dray etching in an embodiment.

Here, in an option, a CMP processing may be additionally performed to preliminarily remove a certain amount of the coating layer 210 before the etching process. However, TSV structure 206 is not suffering the polishing process.

Referring to FIG. 2D, the anisotropic etching process is continuously performed in the next stage until the TSV structure 206 is exposed. Since the flat surface is obtained by the coating layer 210 as shown in FIG. 2, the flat surface may still roughly remain within an acceptable level after the etching process.

As a result, the TSV structure 206 is exposed without involving the polishing process. The interface region between the TSV structure 206 and the dielectric layer 208 in an embodiment is not damaged due to the polishing process, which actually is excluded in the embodiment.

The invention does not limit the subsequent fabrication process, which may further form the other device components and finally strip the carrier 200. The invention provides an improved quality of the TSV structure for the subsequent fabrication process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating semiconductor device, comprising:
providing a preliminary device layer, having a substrate on top and a through substrate via (TSV) structure in the substrate, wherein a top portion of the TSV structure protrudes out from the substrate;
depositing a dielectric layer over the substrate to cover the substrate and the TSV structure;
forming a coating layer over the dielectric layer, wherein the coating layer fully covers over the dielectric layer with a flat surface; and
performing an anisotropic etching process to the coating layer and the dielectric layer without etching selection until the TSV structure is exposed.

2. The method of claim 1, wherein the dielectric layer is oxide layer and the coating layer is a photoresist layer.

3. The method of claim 1, wherein the coating layer with a liquid property provides the flat surface before the anisotropic etching process.

4. The method of claim 1, wherein the coating layer is a dielectric material formed by a spin coating process.

5. The method of claim 1, wherein the coating layer and the dielectric layer are oxide materials as etched by the anisotropic etching process.

6. The method of claim 1, wherein the anisotropic etching process is an etching back process.

7. The method of claim 1, wherein before performing the anisotropic etching process, a polishing process is further performed stating from the coating layer but not to expose the TSV structure.

8. The method of claim 1, wherein a thickness of the dielectric layer is substantially equal to or larger than the top portion of the TSV structure.

9. The method of claim 1, wherein after the anisotropic etching process, the coating layer is fully removed, and a residue of the dielectric layer on the substrate is surrounding the top portion of the TSV structure.

10. The method of claim 1, wherein the TSV structure comprises a metal via; and a liner insulating layer on the sidewall of the metal via to insulate the metal via from the substrate.

11. The method of claim 1, further comprising a subsequent process over the TSV structure and the dielectric layer.

12. The method of claim 1, wherein the substrate is a silicon substrate.

13. The method of claim 1, wherein the dielectric layer comprises an oxide layer, a nitride layer, an oxide layer stacked with a nitride layer, or a first oxide layer stacked with a nitride layer and with a second oxide layer.

14. The method of claim 1, wherein the coating layer is a photoresist layer, and the method further comprises stripping a portion of the photoresist layer.

15. The method of claim 1, wherein the preliminary device layer comprises:
a device layer, disposed on a carrier;
the substrate, disposed on the device layer; and
the TSV structure in the substrate with connection to a device of the device layer.
